(19) United States
(12) Patent Application Publication
(10) Pub. No.: US 2009/0127659 A1
(43) Pub. Date: May 21, 2009

(54) Bipolar junction transistor with a low collector resistance and method of forming the bipolar junction transistor in a CMOS process flow

(76) Inventor: Zia Alan Shafi, San Jose, CA (US)

Correspondence Address: Law Office Of Mark C. Pickering, P.O. Box 151440, San Rafael, CA, 94915-1440, US

(21) Appl. No.: 11/985,429

(22) Filed: Nov. 15, 2007

(51) Int. Cl. H01L 29/73; H01L 21/04

(52) U.S. Cl. 257/565; 438/359; 257/E21.04; 257/E29.174

(57) ABSTRACT

The collector resistance of a bipolar junction transistor that is formed in a CMOS process is substantially reduced by forming a heavily-doped collector extension region that extends from a heavily-doped collector contact region down to a deep well of the same conductivity type to a point that lies close to the base of the transistor.

### BACKGROUND OF THE INVENTION

1. Field of the Invention

The present invention relates to a bipolar junction transistor and, more particularly, to a bipolar junction transistor with a low collector resistance, and a method of forming the bipolar junction transistor in a CMOS process flow.

2. Description of the Related Art

A complementary metal-oxide semiconductor (CMOS) circuit is a circuit that utilizes both n-channel metal-oxide semiconductor (NMOS) and p-channel MOS (PMOS) transistors. One simple CMOS circuit is an inverter. FIG. 1 shows a cross-sectional view that illustrates an example of a prior-art CMOS inverter structure 100.

As shown in the FIG. 1 example, CMOS inverter structure 100 includes a p− semiconductor material 110, such as single-crystal silicon, and a trench isolation region 112 that is formed in p− semiconductor material 110. In addition, CMOS inverter structure 100 includes a PMOS transistor 114 and an NMOS transistor 116.

As further shown in FIG. 1, PMOS transistor 114 includes an n− well 120 that is formed in p− semiconductor material 110, spaced-apart p+ source and drain regions 122 and 124 that are formed in n− well 120, and a channel region 126 that lies between the source and drain regions 122 and 124. PMOS transistor 114 also includes a gate oxide region 128, and a gate 130 that sits on gate oxide region 128 over channel region 126.

NMOS transistor 116, in turn, includes a p− well 132 that is formed in p− semiconductor material 110, spaced-apart n+ source and drain regions 134 and 136 that are formed in p− well 132, and a channel region 138 that lies between the source and drain regions 134 and 136. NMOS transistor 116 also includes a gate oxide region 140, and a gate 142 that sits on gate oxide region 140 over channel region 138. (P− well 132 is optional, but commonly used to control the threshold voltage of NMOS transistor 116.)

Although not shown in the FIG. 1 example, the gates 130 and 142 of the PMOS and NMOS transistors 114 and 116, respectively, are electrically connected together, the drains 124 and 136 of the PMOS and NMOS transistors 114 and 116, respectively, are electrically connected together, the source 122 of PMOS transistor 114 is electrically connected to a power supply line, and the source 134 of NMOS transistor 116 is electrically connected to a ground line.

FIG. 2 shows a cross-sectional view that illustrates another example of a prior-art CMOS inverter structure 200. CMOS inverter structure 200 is similar to CMOS inverter structure 100 and, as a result, utilizes the same reference numerals to designate the elements which are common to both structures.

As shown in the FIG. 2 example, inverter structure 200 differs from inverter structure 100 in that the NMOS transistor 116 of inverter structure 200 also includes a deep n− well 210 that lies between p− semiconductor material 110 and p− well 132. In operation, deep n− well 210 allows p− well 132 to be biased differently than p− substrate 110.

A BiCMOS circuit is a circuit that includes both CMOS transistors and bipolar junction transistors. FIG. 3 shows a cross-sectional view that illustrates an example of a prior-art BiCMOS structure 300. BiCMOS structure 300 is similar to CMOS inverter structure 200 and, as a result, utilizes the same reference numerals to designate the elements which are common to both structures.

As shown in the FIG. 3 example, BiCMOS structure 300 includes inverter structure 200, an npn bipolar transistor 310, and a pnp bipolar transistor 312. NPN transistor 310 includes a deep n− well 314 that is formed in semiconductor material 110, and a p− well 316 that is formed in semiconductor material 110 to touch and lie above deep n− well 314.

As further shown in FIG. 3, NPN transistor 310 also includes a p+ region 320 and an n+ region 322 that are spaced-apart and formed in p− well 316. NPN transistor 310 further includes an n− well 324 that is formed in semiconductor material 110 to touch and lie above deep n− well 314, and an n+ region 326 that is formed in n− well 324. In operation, deep n− well 314, n− well 324, and n+ region 326 function as the collector, p− well 316 functions as the base, p+ region 320 functions as the base contact, and n+ region 322 functions as the emitter.

PNP transistor 312, in turn, includes an n− well 330 that is formed in semiconductor material 110, along with an n+ region 332 and a p+ region 334 that are spaced apart and formed in n− well 330. PNP transistor 312 further includes a p− well 336 that is formed in semiconductor material 110, and a p+ region 338 that is formed in p− well 336. In operation, semiconductor material 110, p− well 336, and p+ region 338 function as the collector, n− well 330 functions as the base, n+ region 332 functions as the base contact, and p+ region 334 functions as the emitter.

One of the advantages of npn and pnp transistors 310 and 312 is that transistors 310 and 312 can be formed utilizing the same process steps as are used to form PMOS and NMOS transistors 114 and 116. Thus, transistors 310 and 312 can be incorporated into a CMOS process flow without any additional masks.

However, one of the disadvantages of npn and pnp transistors 310 and 312 is that since the conventional buried layer is missing, the collector resistance of npn and pnp transistors 310 and 312 is undesirably high. Thus, there is a need for a method of forming npn and pnp transistors in a CMOS process flow that reduces the collector resistance.

### BRIEF DESCRIPTION OF THE DRAWINGS

FIG. 1 is a cross-sectional view illustrating an example of a prior-art CMOS inverter structure 100.

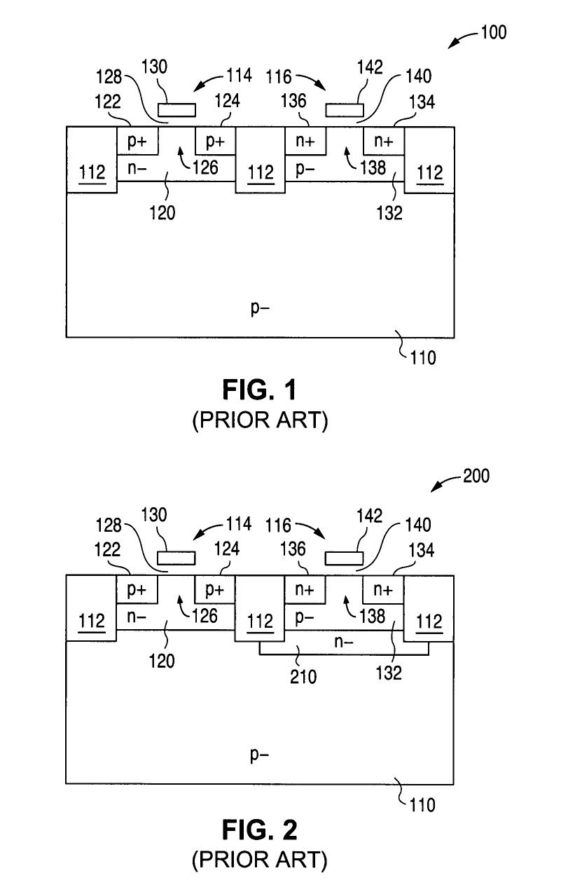

FIG. 2 is a cross-sectional view illustrating another example of a prior-art CMOS inverter structure 200.

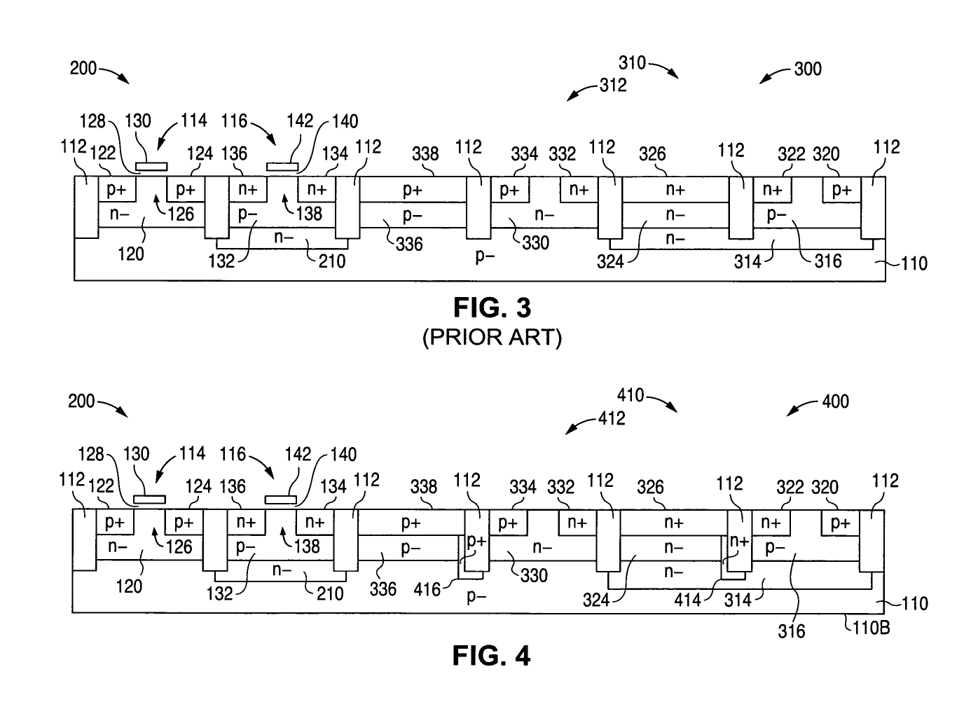

FIG. 3 is a cross-sectional view illustrating an example of a prior-art BiCMOS structure 300.

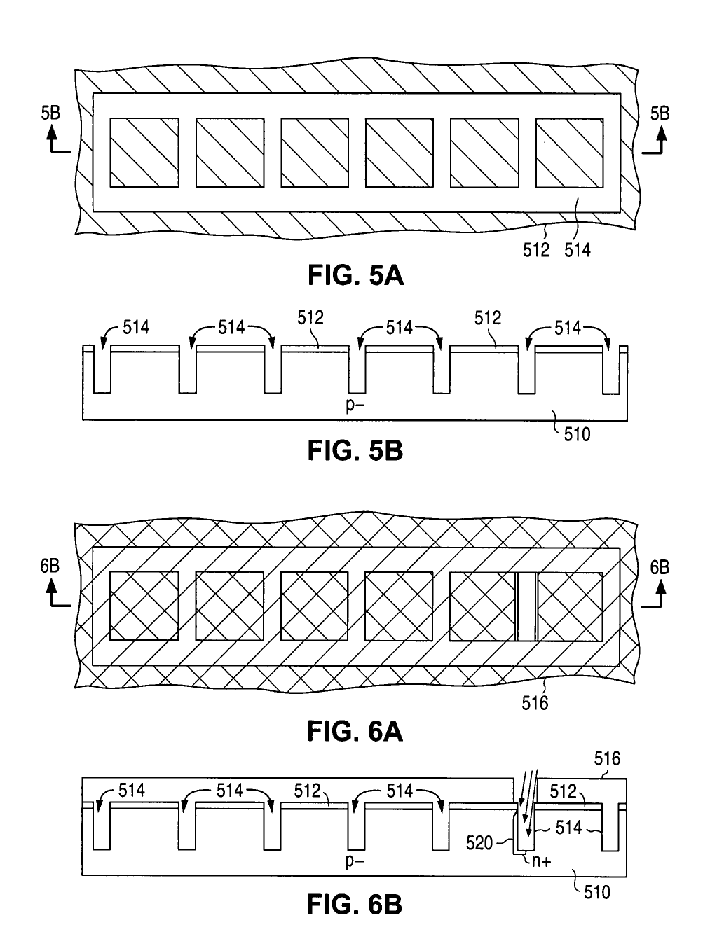

FIG. 4 is a cross-sectional view illustrating an example of a BiCMOS structure 400 in accordance with the present invention.

FIGS. 5A-10A and 5B-10B are views illustrating an example of a method of forming a BiCMOS structure in accordance with the present invention. FIGS. 5A-10A are plan views. FIGS. 5B-10B are cross-sectional views taken along lines 5B-5B to 10B-10B shown in FIGS. 5A-10A, respectively.

### DETAILED DESCRIPTION OF THE INVENTION

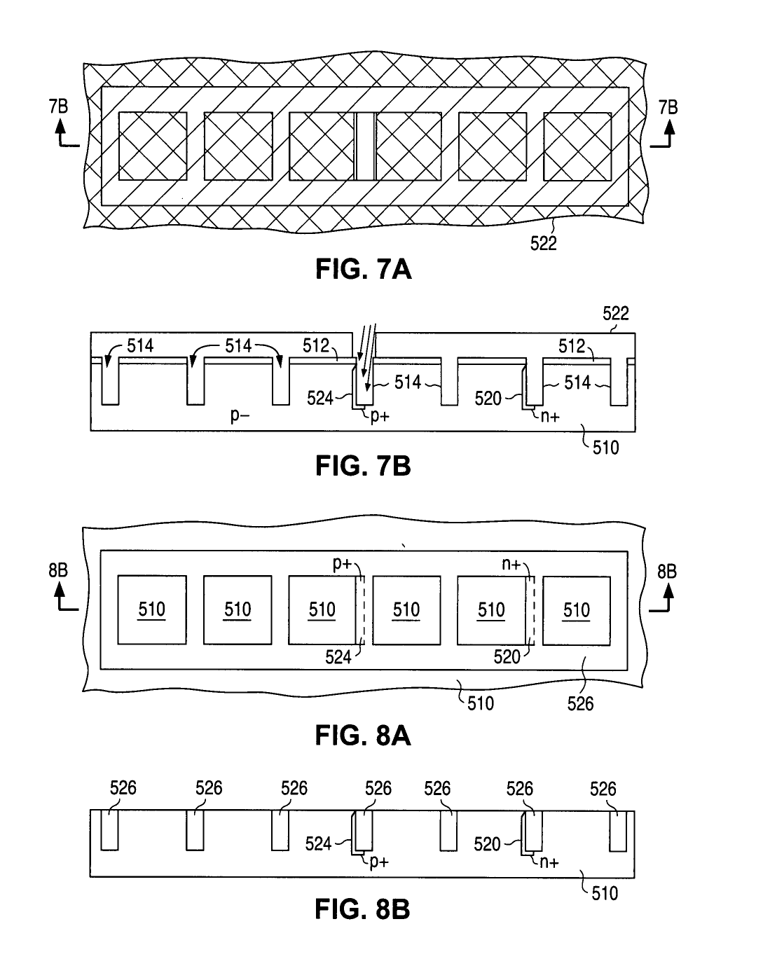

FIG. 4 shows a cross-sectional view that illustrates an example of a BiCMOS structure 400 in accordance with the present invention. As described in greater detail below, BiCMOS structure 400 significantly reduces the collector resistance of the bipolar junction transistors by forming a heavily-doped region that extends along a side wall of the trench isolation region.

As shown in FIG. 4, BiCMOS structure 400 is similar to BiCMOS structure 300 and, as a result, utilizes the same reference numerals to designate the elements which are common to both structures. BiCMOS structure 400 differs from BiCMOS structure 300 in that BiCMOS structure 400 utilizes an npn transistor 410 and a pnp transistor 412 in lieu of npn transistor 310 and pnp transistor 312, respectively.

NPN transistor 410, in turn, is similar to npn transistor 310 and, as a result, utilizes the same reference numerals to designate the structures which are common to both transistors. As further shown in FIG. 4, npn transistor 410 differs from npn transistor 310 in that npn transistor 410 further includes an n+ collector extension region 414 that touches trench isolation region 112, deep n− well 314, and n+ region 326. In addition, n− well 324 may optionally be omitted. In the present example, no n-type region lies between any deep n− well (e.g., 210 and 314) and a region of a bottom side 110B of semiconductor material 110 that lies directly below.

PNP transistor 412 is similar to pnp transistor 312 and, as a result, utilizes the same reference numerals to designate the structures which are common to both transistors. As further shown in FIG. 4, pnp transistor 412 differs from pnp transistor 312 in that pnp transistor 412 further includes a p+ collector extension region 416 that touches semiconductor material 110, trench isolation region 112, and p+ region 338. In addition, p− well 336 may optionally be omitted. In the present example, no p-type region with a dopant concentration greater than a dopant concentration of p− semiconductor material 110 lies between p+ collector extension region 416 and a region of bottom side 110B of semiconductor material 110 that lies directly below.

PMOS transistor 114, NMOS transistor 116, npn transistor 410, and pnp transistor 412 operate in a conventional fashion. NPN transistor 410 and pnp transistor 412, however, have significantly lower collector resistances due to the presence of n+ collector extension region 414 and p+ collector extension region 416, respectively.

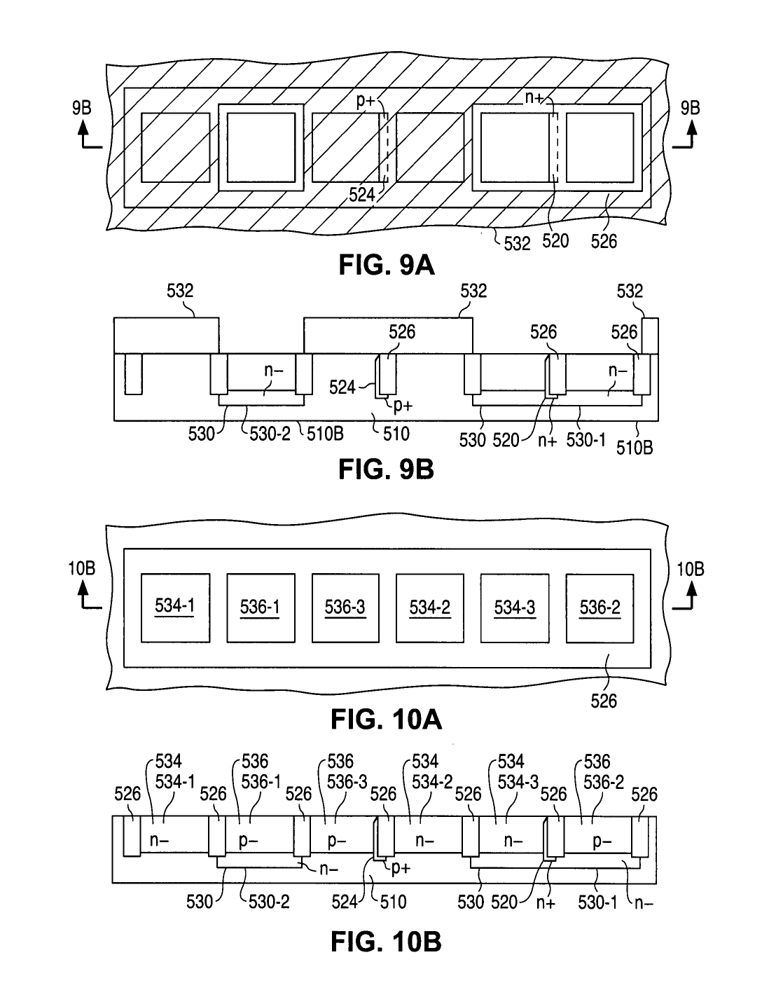

FIGS. 5A-10A and 5B-10B show views that illustrate an example of a method of forming a BiCMOS structure in accordance with the present invention. FIGS. 5A-10A show a series of plan views, while FIGS. 5B-10B show a series of cross-sectional views taken along lines 5B-5B to 10B-10B of FIGS. 5A-10A.

As shown in FIGS. 5A-5B, the method, which utilizes a conventionally-formed p− semiconductor material 510, such as single-crystal silicon, begins by forming a trench isolation region in p− semiconductor material 510. Conventionally, the process to form a trench isolation region begins with the formation and patterning of a mask 512 on the top surface of p− semiconductor material 510. Mask 512 can be formed from, for example, silicon nitride. Following this, the exposed regions of semiconductor material 510 are then etched to form a trench 514.

In accordance with the present invention, as shown in FIGS. 6A-6B, after trench 514 has been formed, a mask 516 is formed and patterned on the top surface of mask 512. Following this, an n-type dopant, such as arsenic, is implanted into p− semiconductor material 510 at an angle of, for example, 30° to form a heavily-doped (n+) collector extension region 520. Due to the angled implant and masks 512 and 516, n+ collector extension region 520 is only formed along one sidewall and a portion of the bottom surface of an exposed trench 514. Mask 516 is then removed.

As shown in FIGS. 7A-7B, once mask 516 has been removed, a mask 522 is formed and patterned on the top surface of mask 512. Following this, a p-type dopant, such as boron, is implanted into p− semiconductor material 510 at an angle of, for example, 30° to form a heavily-doped (p+) collector extension region 524. Due to the angled implant and masks 512 and 522, p+ collector extension region 524 is only formed along one sidewall and a portion of the bottom surface of an exposed trench 514. Mask 522 is then removed.

As shown in FIGS. 8A-8B, once mask 522 has been removed, conventional steps are again followed to form a trench isolation region 526 in trench 514. The conventional steps form a non-conductive material in trench 514, remove the non-conductive material from the top surface of p− semiconductor material 510, and remove mask 512 from the top surface of p− semiconductor material 510.

Next, as shown in FIGS. 9A-9B, once trench isolation region 526 has been formed, a number of deep n− wells 530, including deep n− well 530-1 and 530-2, are formed in p− semiconductor material 510 in a conventional manner. For example, a mask 532 can be formed and patterned on the top surface of semiconductor material 510. Following this, the exposed regions of semiconductor material 510 are implanted with an n-type dopant to form the deep n− wells 530. Mask 532 is then removed. In the present example, no n-type region lies between any deep n− well 530 and a region of a bottom side 510B of semiconductor material 510.

Once mask 532 has been removed, as shown in FIGS. 10A-10B, a number of n− wells 534, including n− well 534-1, n− well 534-2, and n− well 534-3, and a number of p− wells 536, including p− well 536-1, p− well 536-2, and p− well 536-3 are formed in p− semiconductor material 510 in a conventional manner. For example, the wells can be formed by masking and then implanting semiconductor material 510. (N− well 534-3 and p− well 536-3 are optional.)

Following this, a layer of gate oxide is formed on the top surface of semiconductor material 510, followed by the conventional formation of a number of MOS transistor gates. After this, a number of shallow p+ regions and n+ regions are formed in a conventional manner. The regions include spaced-apart p+ source and drain regions that are formed in n− well 534-1 to form a PMOS transistor, like PMOS transistor 114. The regions also include spaced-apart n+ source and drain regions that are formed in p− well 536-1 to form an NMOS transistor, like NMOS transistor 116.

In addition, the regions include an n+ collector that is formed in n− well 534-3 (or p− semiconductor material 510 if n− well 534-3 has been omitted) to touch n+ collector extension region 520, like n+ collector 326, a p+ contact that is formed in p− well 536-2, like p+ contact 320, and an n+ emitter that is formed in p− well 536-2, like n+ emitter 322, which together form an npn transistor, like npn transistor 410.

Further, the regions include a p+collector that is formed in p− well 536-3 (or p− semiconductor material 510 if p− well 536-3 has been omitted), to touch p+ collector extension region 524, like p+ collector 338, an n+ contact that is formed in n− well 534-2, like n+ contact 332, and a p+ emitter that is formed in n− well 534-2, like p+ emitter 334, which together form a pnp transistor, like pnp transistor 412.

Thus, a method has been described for forming a bipolar transistor with a low collector resistance in a CMOS process flow that only requires two additional masks (one for the n+ collector extension implant and one for the p+ collector extension implant).

It should be understood that the above descriptions are examples of the present invention, and that various alternatives of the invention described herein may be employed in practicing the invention. Thus, it is intended that the following claims define the scope of the invention and that structures and methods within the scope of these claims and their equivalents be covered thereby.

What is claimed is:

1. A semiconductor structure comprising:
an isolation structure touching a semiconductor material of a first conductivity type, the semiconductor material having a top surface;
a first well of a second conductivity type touching the semiconductor material, and having a dopant concentration;
a second well of the first conductivity type touching and lying above the first well;
an extension region of the second conductivity type touching the first well, being spaced apart from the second well, and having a dopant concentration that is greater than the dopant concentration of the first well;
a first doped region of the second conductivity type touching the extension region, being spaced apart from and lying above the first well, and having a dopant concentration that is greater than the dopant concentration of the first well, the isolation structure lying laterally between the first doped region and the second well; and
a second doped region of the second conductivity type touching the second well, being spaced apart from the first well, and having a dopant concentration that is greater than the dopant concentration of the first well.

2. The semiconductor structure of claim 1 and further comprising a third doped region of the first conductivity type touching the second well, being spaced apart from the first well and the second doped region, and having a dopant concentration that is greater than the dopant concentration of the second well.

3. The semiconductor structure of claim 2 and further comprising a third well of the second conductivity type touching the first well, the extension region, and the first doped region, being spaced apart from the second well, and having a dopant concentration that is less than the dopant concentration of the extension region and the first doped region.

4. The semiconductor structure of claim 2 and further comprising:
a third well of the second conductivity type touching the semiconductor material, and having a dopant concentration substantially equal to the dopant concentration of the first well;
a fourth well of the first conductivity type touching and lying above the third well;
spaced-apart source and drain regions of the second conductivity type touching the fourth well;
a channel region lying between the source and drain regions; and
a gate lying above the channel region.

5. The semiconductor structure of claim 2 wherein the extension region touches the isolation structure.

6. The semiconductor structure of claim 2 wherein the extension region only touches one side wall and a portion of a bottom surface of the isolation structure.

7. The semiconductor structure of claim 2 wherein the second doped region lies between the first and third doped regions.

8. A method of forming a semiconductor structure comprising:
forming a trench in a semiconductor material of a first conductivity type, the trench having a first side wall, a second side wall opposing the first side wall, and a bottom surface that extends from the first side wall to the second side wall;
implanting a dopant of a second conductivity type into the first side wall and a first portion of the bottom surface to form an extension region, none of the dopant being implanted into the second side wall and a second portion of the bottom surface; and
forming an isolation region in the trench.

9. The method of claim 8 and further comprising:
implanting a dopant of a second conductivity type into the semiconductor material to form a first well; and
implanting a dopant of a first conductivity type into the semiconductor material to form a second well, the second well touching and lying above the first well.

10. The method of claim 9 and further comprising implanting a dopant of a second conductivity type into the semiconductor material to form a first doped region and a second doped region, the first doped region touches the extension region, is spaced apart from and lies above the first well, and has a dopant concentration that is greater than the dopant concentration of the first well.

11. The method of claim 10 wherein the isolation structure lies laterally between the first doped region and the second well.

12. The method of claim 11 wherein the second doped region touches the second well, is spaced apart from the first well, and has a dopant concentration that is greater than the dopant concentration of the first well.

13. The method of claim 12 and further comprising implanting a dopant of a first conductivity type into the second well to form a third doped region that is spaced apart from the first well and the second doped region, the third region having a dopant concentration that is greater than the dopant concentration of the second well.
